(19) United States
(12) Patent Application Publication
(10) Pub. No.: US 2024/0203761 A1
(43) Pub. Date: Jun. 20, 2024

(54) SUBSTRATE TREATING APPARATUS AND SUBSTRATE TREATING SYSTEM INCLUDING THE SAME

(71) Applicant: SEMES CO., LTD., Chungcheongnam-do (KR)

(72) Inventors: Jun Young CHOI, Chungcheongbuk-do (KR); Gui Su PARK, Chungcheongnam-do (KR); Young Jin JANG, Chungcheongnam-do (KR); Eun Jung LEE, Seoul (KR); Hee Jun YOUN, Gyeonggi-do (KR)

(21) Appl. No.: 18/391,599

(22) Filed: Dec. 20, 2023

(30) Foreign Application Priority Data
Dec. 20, 2022 (KR) 10-2022-0179716

(51) Int. Cl. H01L 21/67

(52) U.S. Cl. CPC H01L 21/67086; H01L 21/67057

(57) ABSTRACT

There are provided a substrate treating apparatus and method for etch rate deviation improvement. The substrate treating apparatus includes: a treating bath providing space for receiving a substrate treating solution for treating substrates; a treating solution source providing the substrate treating solution into the treating bath such that the substrates are immersed and treated in the substrate treating solution; and a bubble generation module connected to the treating bath and generating bubbles in the substrate treating solution by injecting gas.

### CROSS-REFERENCE TO RELATED APPLICATION

This application claims priority from Korean Patent Application No. 10-2022-0179716 filed on Dec. 20, 2022 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a substrate treating apparatus and a substrate treating system including the same, and more particularly, a substrate treating apparatus and a substrate treating system including the same, which can be applied to semiconductor manufacturing processes, specifically, a cleaning process.

### 2. Description of the Related Art

Semiconductor manufacturing processes may be performed continuously within semiconductor manufacturing equipment and may be divided into front-end and back-end processes. The front-end process refers to the process of forming circuit patterns on a wafer to complete semiconductor chips, while the back-end process refers to the process of evaluating the performance of the finished products from the front-end process.

Semiconductor manufacturing equipment may be installed within semiconductor fabrication facilities, known as “fabs,” to manufacture semiconductors. Wafers may be moved to undergo various processes such as deposition, photolithography, etching, polishing, ion implantation, cleaning, packaging, and testing, each required for semiconductor production.

When a substrate (e.g., wafer) treating apparatus is provided as batch-type equipment, the substrate treating apparatus can treat multiple substrates simultaneously. The substrates can be submerged and treated in a treating bath that holds a chemical solution.

However, when treating the substrates in the treating bath using the chemical solution, the absence of resistance in the chemical solution may lead to a faster flow rate in the center area, potentially increasing the amount of etching. This may consequently result in a flow of the chemical solution that is unfavorable for distribution.

### SUMMARY

Aspects of the present disclosure provide a substrate treating apparatus for improving etch rate deviations on a substrate and a substrate treating system including the substrate treating apparatus.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a substrate treating apparatus includes: a treating bath providing space for receiving a substrate treating solution for treating substrates; a treating solution source providing the substrate treating solution into the treating bath such that the substrates are immersed and treated in the substrate treating solution; and a bubble generation module connected to the treating bath and generating bubbles in the substrate treating solution by injecting gas.

According to another aspect of the present disclosure, a substrate treating system includes: a first substrate treating apparatus treating a substrate; a second substrate treating apparatus treating the substrate; and a transfer unit transferring the substrate between the first and second substrate treating apparatuses, wherein the first substrate treating apparatus includes a treating bath providing space for receiving a substrate treating solution for treating substrates, a treating solution source providing the substrate treating solution into the treating bath such that the substrates are immersed and treated in the substrate treating solution, and a bubble generation module connected to the treating bath and generating bubbles in the substrate treating solution by injecting gas, and the first and second substrate treating apparatuses differ from each other in terms of how they treat the substrate.

According to another aspect of the present disclosure, a substrate treating apparatus includes: a treating bath providing space for receiving a substrate treating solution for treating substrates; a treating solution source providing the substrate treating solution into the treating bath such that the substrates are immersed and treated in the substrate treating solution; a bubble generation module connected to the treating bath and generating bubbles in the substrate treating solution by injecting gas; and a flow direction control module installed in the treating bath and controlling a movement direction and movement speed of the bubbles, wherein the flow direction control module is a motionless structure installed at an entrance through which the gas is injected into the treating bath, in response to the bubbles colliding with the motionless structure, the movement direction of the bubbles changes, a size of the bubbles is controlled based on shear stress and a size of a hole, which is formed to penetrate the treating bath to provide the gas into the treating bath, and the shear stress is related to a flow rate of the substrate treating solution.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a block diagram illustrating the internal configuration of a substrate treating system, which is provided as hybrid equipment;

FIG. 2 is a schematic view illustrating the internal configuration of a first substrate treating apparatus that constitutes the substrate treatment system;

FIG. 3A is a first exemplary schematic view illustrating how to treat a plurality of substrates with the first substrate treating apparatus;

FIG. 3B is a second exemplary schematic view illustrating how to treat a plurality of substrates with the first substrate treating apparatus;

FIG. 4 is a schematic view illustrating the internal configuration of a second substrate treating apparatus that constitutes the substrate treatment system;

FIG. 5 is a schematic view illustrating the internal configuration of a first substrate treating apparatus for etch rate deviation improvement;

FIG. 6 is a schematic view illustrating the gas injection speed of a bubble generation module that constitutes the first substrate treating apparatus;

FIG. 7 is a first exemplary schematic view illustrating the environment in which the first substrate treating apparatus controls the size of bubbles;

FIG. 8 is a first exemplary schematic view illustrating the layout of treating solution sources that constitute the first substrate treating apparatus;

FIG. 9 is a second exemplary schematic view illustrating the layout of the treating solution sources that constitute the first substrate treating apparatus;

FIG. 10 is a third exemplary schematic view illustrating the layout of the treating solution sources that constitute the first substrate treating apparatus;

FIG. 11 is a second exemplary view illustrating the environment in which the first substrate treating apparatus controls the size of bubbles;

FIG. 12 is a first exemplary schematic view illustrating the layout of bubble generation modules that constitute the first substrate treating apparatus;

FIG. 13 is a second exemplary view illustrating the layout of the bubble generation modules that constitute the first substrate treating apparatus;

FIG. 14 is a third exemplary schematic view illustrating the layout of the bubble generation modules that constitute the first substrate treating apparatus;

FIG. 15 is an exemplary schematic view illustrating the role of flow direction control modules that constitute the first substrate treating apparatus;

FIG. 16 is a first exemplary schematic view illustrating the layout of the flow direction control modules that constitute the first substrate treating apparatus; and

FIG. 17 is a second exemplary schematic view illustrating the layout of the flow direction control modules that constitute the first substrate treating apparatus.

### DETAILED DESCRIPTION

Embodiments of the present disclosure will hereinafter be described with reference to the accompanying drawings. Like reference numerals indicate like elements throughout the present disclosure, and thus, redundant descriptions thereof will be omitted.

The present disclosure relates to a substrate treating apparatus and method capable of improving the dispersion of a substrate treating solution by improving etch rate deviations on a substrate, and will hereinafter be explained in detail with reference to the accompanying drawings.

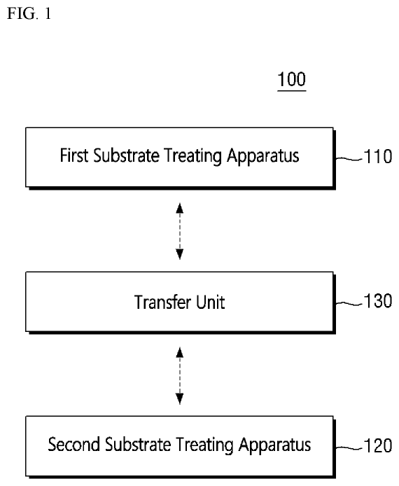

FIG. 1 is a block diagram illustrating the internal configuration of a substrate treating system, which is provided as hybrid equipment. Referring to FIG. 1, a substrate treating system 100 may be configured to include a first substrate treating apparatus 110, a second substrate treating apparatus 120, and a transfer unit 130.

The first and second substrate treating apparatuses 110 and 120 perform treatment on substrates. The first and second substrate treating apparatuses 110 and 120 may be provided as process chambers to perform substrate treatment processes such as a deposition process, a photolithography process, an etching process, and a cleaning process.

One of the first and second substrate treating apparatuses 110 and 120 may be provided as batch-type equipment, while the other may be provided as single-type equipment. Here, batch-type equipment refers to equipment capable of treating multiple substrates simultaneously, whereas single-type equipment refers to equipment that treats each substrate sequentially, one at a time.

However, the present disclosure is not limited to this. Alternatively, the first and second substrate treating apparatuses 110 and 120 may both be provided as batch-type equipment. Yet alternatively, the first and second substrate treating apparatuses 110 and 120 may both be provided as single-type equipment. More detailed explanations of the first and second substrate treating apparatuses 110 and 120 will be presented later.

The transfer unit 130 transports substrates between the first and second substrate treating apparatuses 110 and 120. The transfer unit 130 may transfer substrates from the first substrate treating apparatus 100 to the second substrate treating apparatus 120, but the present disclosure is not limited thereto. The transfer unit 130 may also transfer substrates from the second substrate treating apparatus 120 to the first substrate treating apparatus 110. The transfer unit 130 may also transfer substrates between the first and second substrate treating apparatuses 110 and 120. The transfer unit 130 may be implemented as a transfer module.

The transfer unit 130 may transfer substrates from batch-type equipment to single-type equipment, but the present disclosure is not limited thereto. Alternatively, the transfer unit 130 may also transfer substrates from one batch-type equipment to another batch-type equipment. Yet alternatively, the transfer unit 130 may transfer substrates from one single-type equipment to another single-type equipment.

The first and second substrate treating apparatuses 110 and 120 will hereinafter be described as being provided as batch-type equipment and single-type equipment, respectively, and the transfer unit 130 will hereinafter be described as transferring substrates from the first substrate treating apparatus 110 to the second substrate treating apparatus 120.

When the first substrate treating apparatus 110 is implemented as batch-type equipment, the first substrate treating apparatus 110 may immerse multiple substrates in a bath containing a treating solution. For example, the first substrate treating apparatus 110 may perform prewetting on multiple substrates by immersing the substrates in a bath filled with de-ionized water (DIW). In another example, the first substrate treating apparatus 110 may perform etching on multiple substrates by immersing the substrates in a bath containing a first treating solution. In another example, the first substrate treating apparatus 110 may perform rinsing on multiple substrates by immersing the substrates in a bath containing a second treating solution.

The first treating solution may be a chemical. For example, the first treating solution may be a chemical with properties of a strong acid or a strong alkali. In this example, the first treating solution may be selected from among chemicals such as ammonia-hydrogen peroxide mixture (or a SC-1 cleaning solution), hydrochloric acid-hydrogen peroxide mixture (or a SC-2 cleaning solution, hydrofluoric acid-hydrogen peroxide mixture (FPM), diluted hydrofluoric acid (DHF), chemicals for removing SiN, chemicals containing phosphoric acid, and chemicals containing sulfuric acid.

The second treating solution may be a rinse solution. The second treating solution may be selected from among pure water, ozone water, and the like.

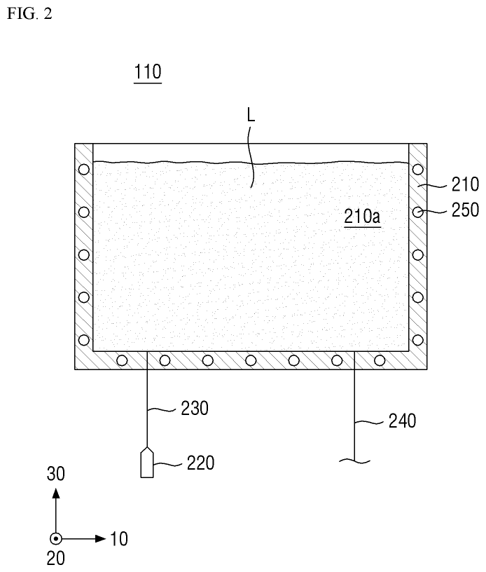

If the first substrate treating apparatus 110 treats multiple substrates by immersing the substrates in baths containing the first treating solution, the second treating solution, or other substrate treating solutions for etching, rinsing, etc., the first substrate treating apparatus 110 may be configured, as illustrated in FIG. 2, to include a bath, a treating solution supply source 220, a treating solution supply line 230, a treating solution discharge line 240, and a first heating member 250.

FIG. 2 is a schematic view illustrating the internal configuration of a first substrate treating apparatus that constitutes the substrate treatment system.

Referring to FIG. 2, a treating bath 210 may have an internal accommodating space 210a capable of holding a substrate treating solution L. The treating bath 210 may have a cylindrical shape with an open upper end. The treating bath 210 may include sidewalls extending in an upward direction (e.g., in a third direction 30) from the edges of its bottom as viewed from the top.

The liquid supply source 220 may supply the substrate treating solution L, such as the first treating solution or the second treating solution, to the accommodating space 210a of the treating bath 210. The treating solution supply source 220 may be connected to the treating solution supply line 230. One end of the treating solution supply line 230 may be connected to the accommodating space 210a of the treating bath 210, while the other end of the treating solution supply line 230 may be connected to the treating solution supply source 220. The treating solution supply source 220 supplies the substrate treating solution L through the treating solution supply line 230, and the treating solution supply line 230 may supply the substrate treating solution L to the accommodating space 210a of the treating bath 210. Also, the substrate treating solution L used in the accommodating space 210a of the treating bath 210 may be discharged externally through the treating solution discharge line 240.

The first heating member 250 may regulate the temperature of the substrate treating solution L supplied to the accommodating space 210a of the treating bath 210. For example, the first heating member 250 may heat the substrate treating solution L supplied to the accommodating space 210a of the treating bath 210 to a predetermined temperature. The first heating member 250 may be provided on the bottom and the sidewalls of the treating bath 210. Alternatively, the first heating member 250 may be positioned within the treating bath 210.

The first heating member 250 may generate heat or cold to control the temperature of the substrate treating solution L supplied to the accommodating space 210a of the treating bath 210. The first heating member 250 may be a heater, but the present embodiment is not limited thereto. The first heating member 250 may be variably modifiable and applicable to nearly any type of device as disclosed, as long as it can efficiently control the temperature of the substrate treating solution supplied to the accommodating space 210a of the treating bath 210.

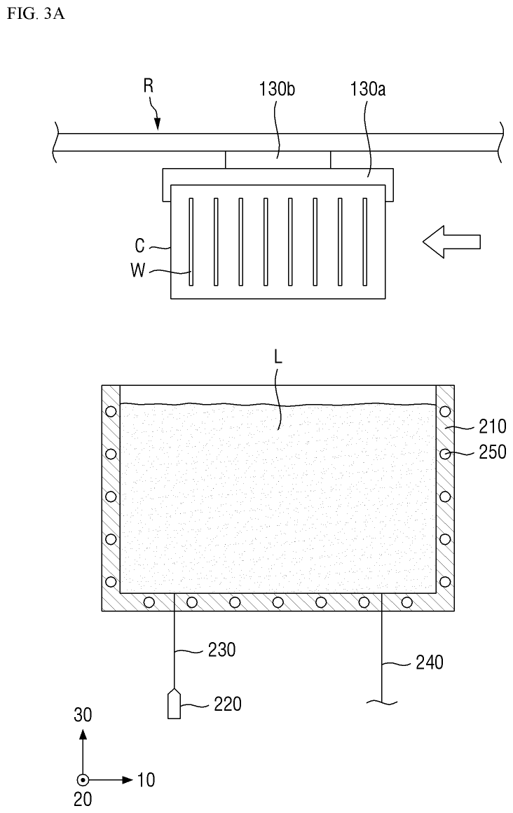

FIG. 3A is a first exemplary schematic view illustrating how to treat a plurality of substrates with the first substrate treating apparatus. FIG. 3B is a second exemplary schematic view illustrating how to treat a plurality of substrates with the first substrate treating apparatus.

Referring to FIGS. 2, 3A, and 3B, a container C containing a plurality of substrates W, for example, around 25 to 50 substrates W, may be immersed in the substrate treating solution L, which is supplied to the accommodating space 210a of the treating bath 210 by the transfer unit 130.

Specifically, first, as illustrated in FIG. 2, the substrate treating solution L is introduced into the accommodating space 210a of the treating bath 210 to fill the accommodating space 210a with the substrate treating solution L.

Thereafter, as illustrated in FIG. 3A, with a gripping section 130a of the transfer unit 130 holding the container C, a driving section (not illustrated) of the transfer unit 130 moves upward along a rail R toward an upper part of the treating bath 210.

Thereafter, as illustrated in FIG. 3B, a lifting section 130b of the transfer unit 130 descends and places the container C into the accommodating space 210a of the treating bath 210. In this case, the multiple substrates W stored in the container C may maintain their vertical posture.

Following the sequential steps illustrated in FIGS. 2, 3A, and 3B, the container C becomes immersed in the substrate treating solution L within the accommodating space 210a of the treating bath 210. Then, the substrate treating solution L flows into the storage space of the container C, allowing the treatment of the multiple substrates W.

If the first substrate treating apparatus 110 is implemented as batch-type equipment and the second substrate treating apparatus 120 is implemented as single-type equipment, the second substrate treating apparatus 120 may perform the drying of each substrate rinsed with the second treating solution. For example, the second substrate treating apparatus 120 may use a spin-drying process or employ a supercritical drying process to dry each substrate.

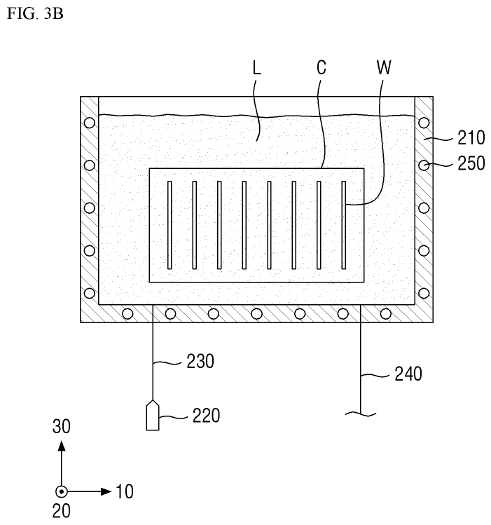

The drying of each substrate via a supercritical drying process will hereinafter be described. FIG. 4 is a schematic view illustrating the internal configuration of a second substrate treating apparatus that constitutes the substrate treatment system.

Referring to FIG. 4, a second substrate treating apparatus 120 may include a housing 310, a lifting unit 320, a support unit 330, a second heating member 340, a fluid supply unit 350, a blocking member 360, and an exhaust member 370.

The second substrate treating apparatus 120 may process a substrate W using a supercritical fluid. For example, the second substrate treating apparatus 120 may dry the substrate W using carbon dioxide (CO₂) as the supercritical fluid.

The housing 310 provides a treatment space where a supercritical drying process takes place. The housing 310 may be formed of a material capable of withstanding pressures higher than a critical pressure.

The housing 310 includes an upper module 310a and a lower module 310b. The lower module 310b is coupled to and provided below the upper module 310a. The combined space created by the upper module 310a and the lower module 310b serves as a substrate treatment space.

The upper module 310a is fixedly installed to an external structure. The lower module 310b is provided to be liftable with respect to the upper module 310a. When the lower module 310b descends and separates from the upper module 310a, the treatment space within the second substrate treating apparatus 120 is opened. The substrate W may then be introduced into or removed from the interior space of the second substrate treating apparatus 120.

The substrate W introduced into the second substrate treating apparatus 120 may be in a state where a cleaning liquid (e.g., DIW) remains. When the lower module 310b rises and adheres to the upper module 310a, the interior treatment space of the second substrate treating apparatus 120 is sealed. Within the sealed treatment space, the substrate W may be treated using the supercritical fluid. Alternatively, the housing 310 may have a structure where the lower module 310b is fixedly installed, while the upper module 310a is designed to be liftable. The lifting unit 320 raises the lower module 310b. The lifting unit 320 includes a

lifting cylinder 320a and a lifting rod 320b. The lifting cylinder 320a is coupled to the lower module 310b and generates a vertical driving force. During the treatment of the substrate W using the supercritical fluid, the lifting cylinder 320a generates a sufficient driving force to overcome pressures above the critical pressure inside the second substrate treating apparatus 120 and to seal the second substrate treating apparatus 120 by adhering the upper module 310a and the lower module 310b. One end of the lifting rod 320b is inserted into the lifting cylinder 320a and extends in a vertical upward direction (e.g., the third direction 30), and the other end of the lifting rod 320b is coupled to the upper module 310a.

When the lifting cylinder 320a generates a driving force, the lifting cylinder 320a and the lifting rod 320b are relatively raised, and the lower module 310b, which is coupled to the lifting cylinder 320a, can be lifted. While the lower module 310b is lifted by the lifting cylinder 320a, the lifting rod 320b guides the lifting direction of the lower module 310b and prevents the upper and lower modules 310a from moving in a horizontal direction (e.g., a first direction 10 or a second direction 20), thereby preventing the upper and lower modules 310a from disengaging from their proper positions.

The support unit 330 is positioned in the treatment space of the housing 310 and supports the substrate W. The support unit 330 is coupled to the upper module 310a. The support unit 330 includes vertical portions 330a and a horizontal portion 330b.

The vertical portions 330a extend downward from the upper wall of the housing 310. The vertical portions 330a are installed on the bottom surface of the upper module 310a. The vertical portions 330a further extend beneath the upper module 310a. The ends of the vertical portions 330a are vertically connected to the horizontal portion 330b. The horizontal portion 330b extends inward from the ends of the vertical portions 330a towards the inside of the housing 310. The substrate W is placed on the horizontal portion 330b. The horizontal portion 330b supports the bottom surface of the edge area of the substrate W.

The support unit 330 contacts the edge area of the substrate W, providing support to the entire top surface and most of the bottom surface of the substrate W during treatment with the supercritical fluid. Here, the substrate W may have a patterned top surface and a non-patterned bottom surface.

The support unit 330 is installed on the upper module 310a. The support unit 330 may stably support the substrate W while the lower module 310b is being lifted.

A horizontal adjustment member 380 is installed in the upper module 310a, in which the support unit 330 is installed. The horizontal adjustment member 380 adjusts the level of the upper module 310a. By adjusting the level of the upper module 310a, the horizontal alignment of the substrate W supported by the support unit 330 on the upper module 310a is also controlled. When the upper module 310a is lifted and the lower module 310b is fixedly installed, or when the support unit 330 is installed on the lower module 310b, the horizontal adjustment member 380 may also be installed in the lower module 310b.

The second heating member 340 heats the interior of the second substrate treating apparatus 120. The second heating member 340 maintains the supercritical fluid in a supercritical state by heating the supercritical fluid supplied into the second substrate treating apparatus 120 to a temperature above the critical temperature. When the supercritical fluid is liquefied, the second heating member 340 may reheat the supercritical fluid to revert the supercritical fluid back to the supercritical state. The second heating member 340 is buried within at least one of the walls of the upper module 310a or the lower module 310b. The second heating member 340 receives power from an external source to generate heat. The second heating member 340 may be provided, for example, as a heater.

The fluid supply unit 350 supplies fluid to the second substrate treating apparatus 120. The supplied fluid may be the supercritical fluid. In some embodiments, the supercritical fluid may be carbon dioxide.

The fluid supply unit 350 may include an upper fluid supply section 350a, a lower fluid supply section 350b, a supply pipe 350c, valves 350d and 350e, and a supercritical fluid storage section 350f.

The upper fluid supply section 350a directly supplies the supercritical fluid to the top surface of the substrate W. The upper fluid supply section 350a is connected to the upper module 310a. The upper fluid supply unit 350a is connected to a part of the upper module 310a that is directed towards the central top surface of the substrate W.

The lower fluid supply section 350b supplies the supercritical fluid to the bottom surface of the substrate W. The lower fluid supply section 350b is connected to the lower module 310b. The lower fluid supply section 350b is connected to a part of the lower module 310b that is directed towards the central bottom surface of the substrate W.

The supercritical fluid sprayed from the upper and lower fluid supply sections 350a and 350b reaches the central area of the substrate W and spreads towards the edge area, providing a uniform distribution over the entire surface of the substrate W.

The supply pipe 350c is connected to both the upper and lower fluid supply sections 350a and 350b. The supply pipe 350c receives the supercritical fluid from a separate supercritical fluid storage section 350f, and supplies the supercritical fluid to the upper and lower fluid supply sections 350a and 350b.

The valves 350d and 350e are installed in the supply pipe 350c. Multiple valves 350d and 350e may be provided in the supply line. Each of the valves 350d and 350e controls the flow rate of the supercritical fluid supplied to the upper and lower fluid supply sections 350a and 350b. Although not specifically illustrated in FIG. 3, the valves 350d and 350e may also control the flow rate of the supercritical fluid supplied into the housing 310 by a control device.

The fluid supply unit 350 first supplies the supercritical fluid to the lower fluid supply section 350b. Thereafter, the fluid supply unit 350 may supply the supercritical fluid to the upper fluid supply section 350a. A supercritical drying process may be conducted when the interior of the second substrate treating apparatus 120 is not yet at the critical pressure. If the interior of the second substrate treating apparatus 120 is below the critical pressure, the supercritical fluid supplied into the second substrate treating apparatus 120 may liquefy. When the supercritical fluid is liquefied, the supercritical fluid may fall onto the substrate W due to gravity, potentially causing damage to the substrate W.

Therefore, the lower fluid supply section 350b first supplies the supercritical fluid. After the supercritical fluid is supplied to the second substrate treating apparatus 120, the internal pressure of the second substrate treating apparatus 120 reaches the critical pressure. Once the internal pressure of the second substrate treating apparatus 120 reaches the critical pressure, the upper fluid supply section 350a supplies supercritical fluid. By supplying supercritical fluid from the lower fluid supply section 350b before from the upper fluid supply section 350a, the supercritical fluid can be prevented from liquefying and falling onto the substrate W.

The blocking member 360 prevents the supercritical fluid supplied from the fluid supply unit 350 from being sprayed directly on the bottom surface of each of the substrate W. The blocking member 360 includes a blocking plate 360a and support elements 360b.

The blocking plate 360a is positioned inside the housing 310, i.e., within the treatment space. The blocking plate 360a is placed between the support unit 330 and the lower fluid supply section 350b. The blocking plate 360a has a shape corresponding to the shape of the substrate W. For example, the blocking plate 360a may have a circular plate shape. The radius of the blocking plate 360a may be similar to or larger than that of the substrate W. By placing the blocking plate 360a on the bottom surface of the substrate W supported by the support unit 330, the supercritical fluid supplied through the lower fluid supply section 350b is prevented from being directly sprayed on the lower surface of the substrate W. When the radius of the blocking plate 360a is similar to or larger than the radius of the substrate W, the blocking plate 360a can completely block the supercritical fluid from directly impinging on the substrate W.

On the contrary, the radius of the blocking plate 360a may be smaller than the radius of the substrate W. In this case, the blocking plate 360a prevents the supercritical fluid from directly impinging on the substrate W. Additionally, the blocking plate 360a minimizes the flow rate of the supercritical fluid, allowing the supercritical fluid to reach the substrate W relatively easily. When the radius of the blocking plate 360a is smaller than the radius of the substrate W, the supercritical drying process for the substrate W can be effectively conducted.

The support elements 360b support the blocking plate 360a. The support elements 360b support the rear surface of the blocking plate 360a. The support elements 360b are installed on the lower wall of the housing 310 in the vertical direction (or the third direction 30). The support elements 360b and the blocking plate 360a may be positioned on the support elements 360b by the gravity of the blocking plate 360a without any particular coupling.

On the other hand, the support elements 360b and the blocking plate 360a may be coupled using coupling means such as nuts or bolts. Alternatively, the support elements 360b and the blocking plate 360a may be integrally formed.

The exhaust member 370 discharges the supercritical fluid from the second substrate treating apparatus 120. The exhaust member 370 may be connected to an exhaust line for discharging the supercritical fluid. Although not specifically illustrated in FIG. 3, a valve may be installed on the exhaust member 370 to control the flow rate of the supercritical fluid discharged to the exhaust line.

The supercritical fluid discharged through the exhaust line may be released into the atmosphere. Alternatively, the supercritical fluid may be supplied to a supercritical fluid regeneration system. The exhaust member 370 may be coupled to the lower module 310b.

At a later stage of the substrate treatment process using the supercritical fluid, the internal pressure of the second substrate treating apparatus 120 is depressurized below the critical pressure as the supercritical fluid is discharged. The liquefied supercritical fluid may be discharged through the exhaust member 370, which is formed in the lower module 310b due to gravity.

As previously described, the treating solution source 220 supplies a substrate treating solution L to the treating bath 210. When the container C with a plurality of substrates W is immersed in the substrate treating solution L within the treating bath 210, each of the substrates W may be subjected to etching treatment by the substrate treating solution L.

However, within the treating bath 210, there is little to no flow of the substrate treating solution L, and consequently no resistance to such flow. Therefore, if a flow velocity occurs in a particular area (for example, the center area), the etch amount in the particular area may increase, and this may lead to a decrease in the dispersion of the substrate treating solution L and a decrease in the etch rate of the substrates W. By improving the ER deviations on the substrates W, the dispersion of the substrate treating solution L can be improved. Measures to improve the ER deviations in the first substrate treating apparatus 110 will hereinafter be described.

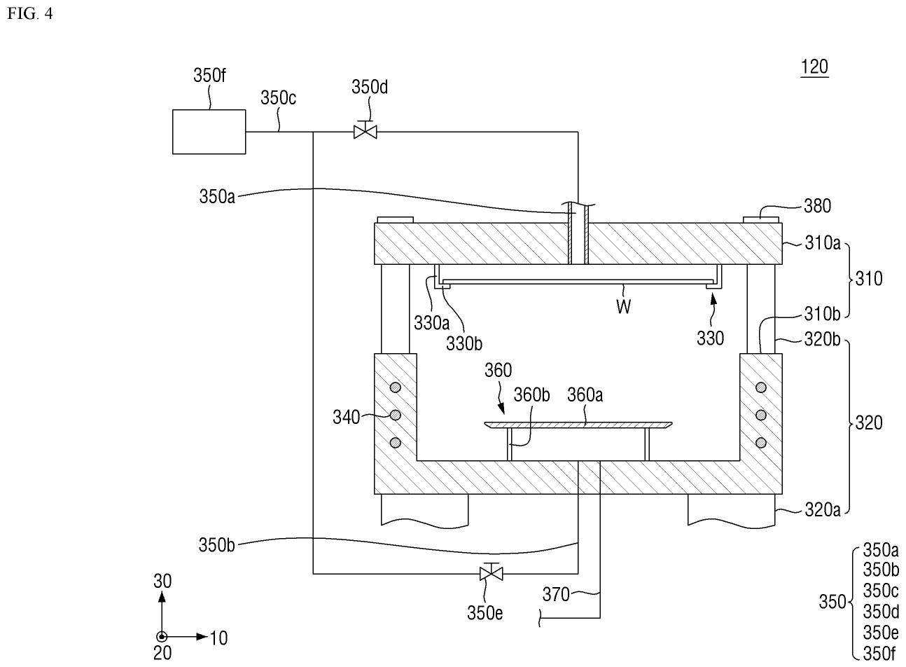

FIG. 5 is a schematic view illustrating the internal configuration of a first substrate treating apparatus for etch rate deviation improvement. Referring to FIG. 5, the first substrate treating apparatus 110 may be configured to include the treating bath 210, the treating solution source 220, the treating solution supply line 230, the treating solution discharge line 240, the first heating element 250, a bubble generation module 410, and flow direction control modules 420.

The treating bath 210, the treating solution source 220, the treating solution supply line 230, the treating solution discharge line 240, and the first heating element 250 have already been described with reference to FIGS. 2 through 3B, and thus, further details thereof will be omitted. Instead, only the bubble generation module 410 and the flow direction control modules 420 will hereinafter be described.

The bubble generation module 410 generates bubbles within the substrate treating solution L. The bubble generation module 410 may inject gas into the substrate treating solution L, thereby allowing bubbles to be formed. For example, nitrogen (N₂) gas may be supplied as the gas injected into the substrate treating solution L by the bubble generation module 410.

By generating bubbles in the substrate treating solution L using the bubble generation module 410, it becomes possible to control the etch amount (or etch rate) for the substrates W and thereby effectively regulate the dispersion of the substrate treating solution L. For example, generating bubbles in the substrate treating solution L while etching the substrates W with the substrate treating solution L may reduce the dispersion of the substrate treating solution L. To control the etching amount for the substrates W, the bubble generation module 410 may regulate the injection speed of the gas supplied into the treating bath 210.

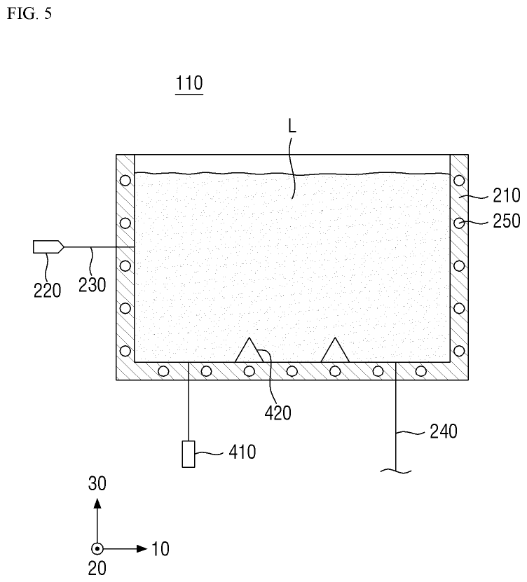

Referring to FIG. 6, the bubble generation module 410 may inject gas into the treating bath 210 at a first velocity V₁. In this case, bubbles may be generated at a reference velocity V_{REF} on an inner surface 430a of the treating bath 210 that comes into contact with the substrate treating solution L. FIG. 6 is a schematic view illustrating the gas injection speed of the bubble generation module that constitutes the first substrate treating apparatus.

To control the dispersion of the substrate treating solution L by reducing the dispersion of the substrate treating solution L either significantly within a short period of time or gradually over a particular period of time, the bubble generation module 410 may vary the gas injection speed based on the first velocity V₁, thereby altering the amount of bubbles generated within the substrate treating solution L.

For example, the bubble generation module 410 may inject gas into the substrate treating solution L at a second velocity V₂. The second velocity V₂ may be greater than the first velocity V₁ (i.e., V₂>V₁). Alternatively, the bubble generation module 410 may inject gas at a third velocity V₃. The third velocity V₃ may be greater than both the first velocity V₁ and the second velocity V₂ (i.e., V₃>V₂>V₁).

By injecting gas into the substrate treating solution L at the second and third velocities V₂ and V₃, which are faster the first velocity V₁, the bubble generation module 410 may generate bubbles on the inner surface 430a of the treating bath 210 at speeds faster (i.e., “V_{F}” and “V_{VF}”) than the reference velocity V_{REF}. In this case, the amount of bubbles generated within the substrate treating solution L may increase at a faster rate, and the rate at which the dispersion of the substrate treating solution L decreases may also increase quickly.

The bubble generation module 410 may also inject gas at a fourth velocity V₄. The fourth velocity V₄ may be smaller than the first velocity V₁ (i.e., V₄<V₁). Alternatively, the bubble generation module 410 may inject gas at a fifth velocity V₅. The fifth velocity V₅ may be smaller than both the first and fourth velocities V₁ and V₄ (i.e., V₅<V₄<V₁).

By injecting gas at the fourth and fifth velocities V₄ and V₅, which are slower than the first velocity V₁, the bubble generation module 410 may generate bubbles on the inner surface 430a of the treating bath 210 at slower speeds (i.e., “V_{S}” and “V_{VS}”) than the reference velocity V_{REF}. In this case, the amount of bubbles generated within the substrate treating solution L may increase at a slower rate, and the rate at which the dispersion of the substrate treating solution L decreases may also increase more slowly.

As previously explained, the etch amount or etch rate for the substrates W may be controlled by the amount of bubbles generated by the bubble generation module 410, but the present disclosure is not limited thereto. Alternatively, the etch amount or etch rate for the substrates W may also be controlled by the size of the bubbles generated. For example, smaller bubble sizes may increase the area in contact with the substrate treating solution L, potentially leading to an increase in the etch amount.

The size of bubbles 510 may be controlled based on the type of gas provided by the bubble generation module 410 and the size of a hole 430d, which is formed to supply the gas into the treating bath 210.

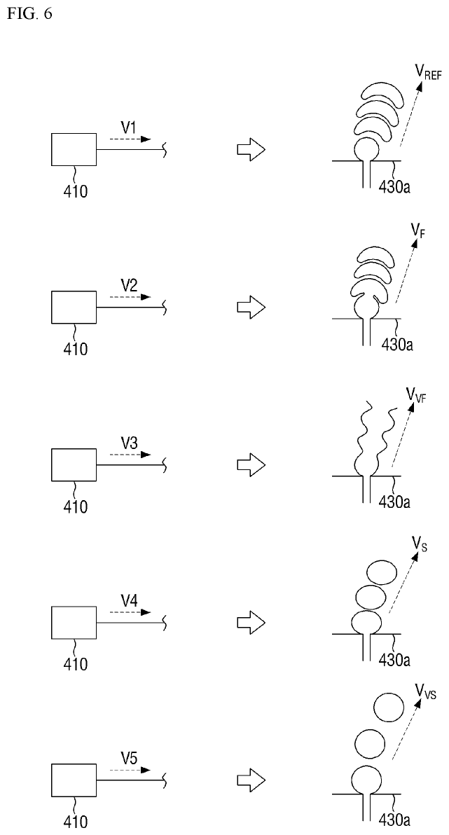

Internal factors for the size of the bubbles 510 may be determined by the relationship between the hole 430d and the supplied gas. However, referring to FIG. 7, if external factors such as shear stress 520 arise, the bubbles 510 may be detached with a smaller size from the inner surface 430a of the treating bath 210. The size of the bubbles 510 may be controlled in consideration of the shear stress 520 applied around the hole 430d, in addition to the type of gas supplied by the bubble generation module 410 and the size of the hole 430d, which is provided to allow the supplied gas to move into the treating bath 210. FIG. 7 is a first exemplary schematic view illustrating the environment in which the first substrate treating apparatus controls the size of bubbles.

By increasing the shear stress 520, it becomes possible to generate smaller bubbles 510, and smaller bubbles 510 may improve the circulation of the substrate treating solution L within the treating bath 210. A smaller bubble size also increases the area of contact between the substrates W and the substrate treating solution L, potentially improving etch rate performance. Additionally, the size of the bubbles 510 may be adjusted without changing the gas flow rate by utilizing the shear stress 520.

The shear stress 520 is related to the flow rate of the substrate treating solution L in the treating bath 210. Flow of the substrate treating solution L may be induced for the shear stress 520. To cause flow of the substrate treating solution L, the number and position of treating solution sources 220 connected to the treating bath 210 may be adjusted. Alternatively, the position of the treating solution source 220 connected to the treating bath 210 may be adjusted. Yet alternatively, the movement speed of the substrate treating solution L supplied by the treating solution source 220 may be controlled.

The flow rate of the substrate treating solution L may also be related to the bubble generation module 410. The number and position of bubble generation modules 410 connected to the treating bath 210 may be adjusted. Alternatively, the injection speed of the gas provided by the bubble generation module 410 may also be controlled.

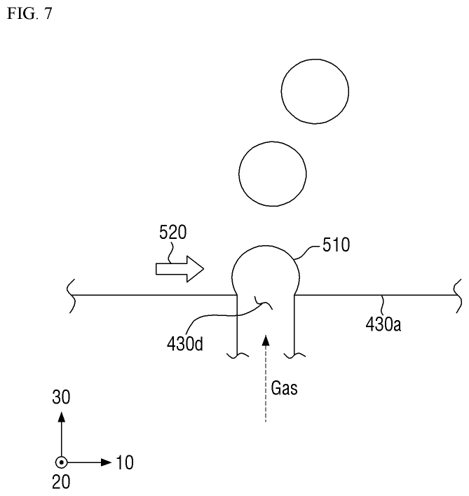

Referring to FIG. 8, a plurality of treating solution sources 220a, 220b, . . . , and 220n may be connected to the treating bath 210 through a bottom surface 430b and sidewalls 430c of the treating bath 210. FIG. 8 is a first exemplary schematic view illustrating the layout of a plurality of treating solution sources that constitute the first substrate treating apparatus.

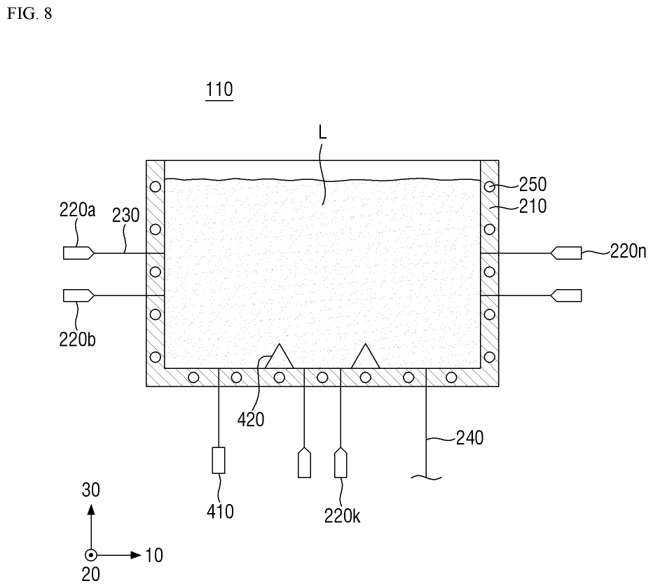

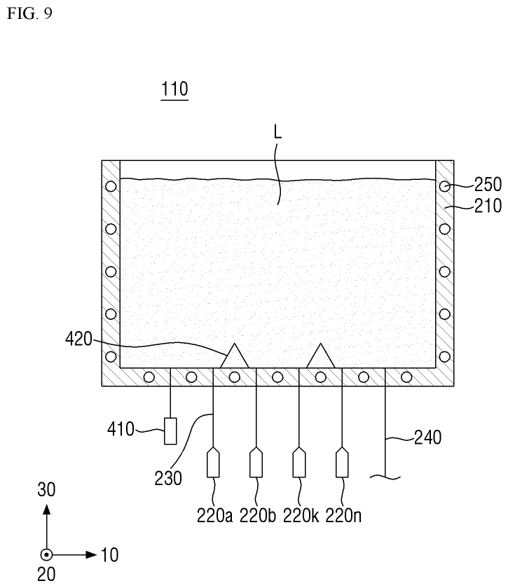

However, the present disclosure is not limited to this. Alternatively, referring to FIG. 9, the treating solution sources 220a, 220b, . . . , and 220n may be connected to the treating bath 210 only through the bottom surface 430b of the treating bath 210. Yet alternatively, referring to FIG. 10, the treating solution sources 220a, 220b, . . . , and 220n may be connected to the treating bath 210 only through the sidewalls 430c 430b of the treating bath 210. FIG. 9 is a second exemplary schematic view illustrating the layout of the plurality of treating solution sources that constitute the first substrate treating apparatus. FIG. 10 is a third exemplary schematic view illustrating the layout of the plurality of treating solution sources that constitute the first substrate treating apparatus.

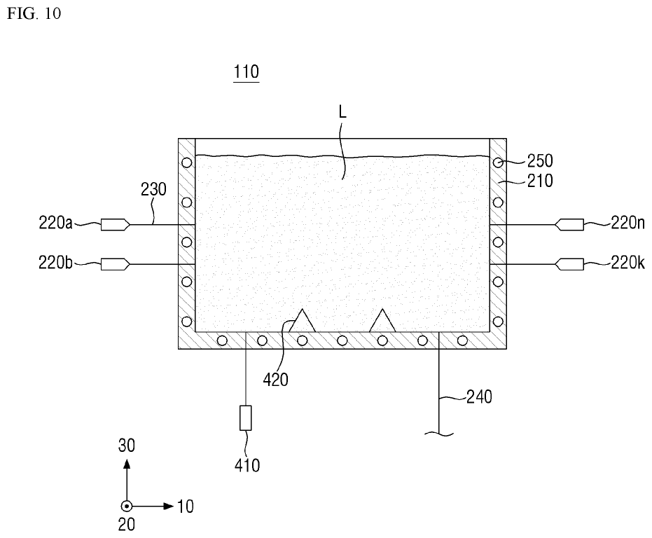

Meanwhile, after supplying the substrate treating solution L into the treating bath 210, the treating bath 210 may be rotated for a predetermined amount of time, as illustrated in FIG. 11, to induce flow in the substrate treating solution L within the treating bath 210. In this case, after the rotation of the treating bath 210 has stopped, bubbles may be generated in the substrate treating solution L by the bubble generation module 410. The first substrate treating apparatus 110 may further include a driving control module 440, which is for rotating the treating bath 210. FIG. 11 is a second exemplary view illustrating the environment in which the first substrate treating apparatus controls the size of bubbles.

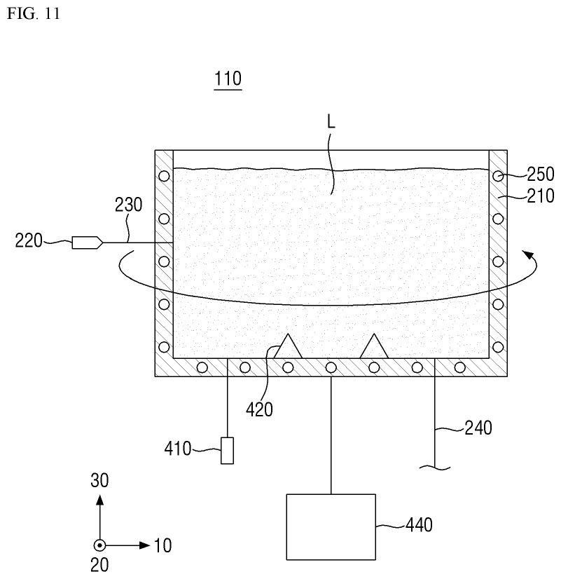

A single bubble generation module 410 may be installed within the treating bath 210, but the present disclosure is not limited thereto. Alternatively, referring to FIG. 12, a plurality of bubble generation modules 410a, 410b, . . . , 410k, . . . , and 410n may be installed to be evenly connected over the bottom surface 430b and sidewalls 430c of the treating bath 210. FIG. 12 is a first exemplary schematic view illustrating the layout of a plurality of bubble generation modules that constitute the first substrate treating apparatus.

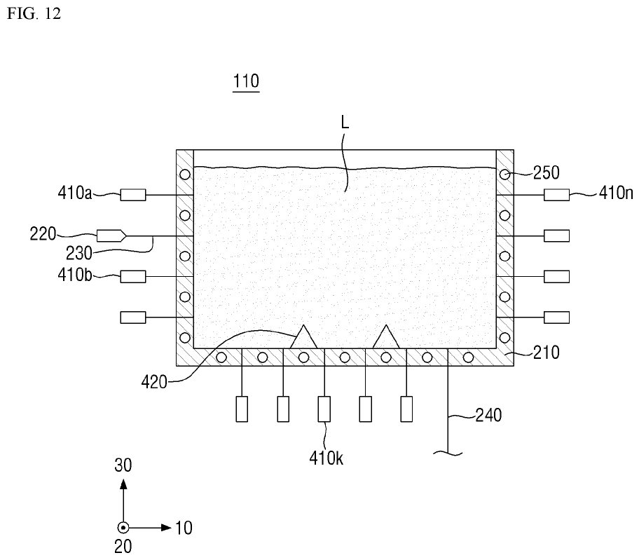

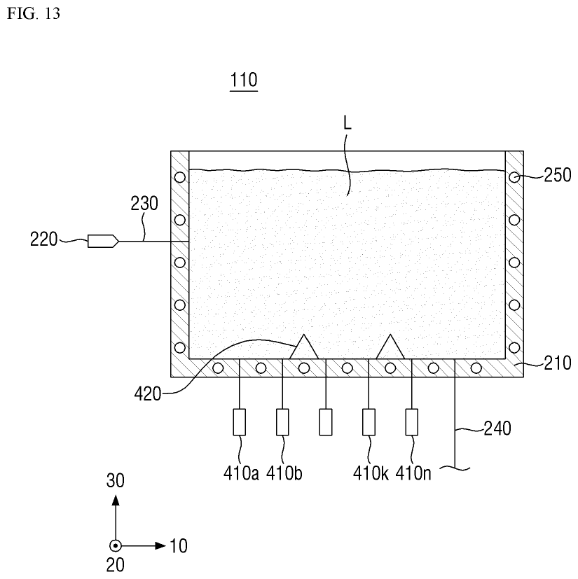

However, the present disclosure is not limited to this. Alternatively, referring to FIG. 13, the bubble generation modules 410a, 410b, . . . , 410k, . . . , and 410n may also be connected and installed only on the bottom surface 430b of the treating bath 210. Yet alternatively, referring to FIG. 14, the bubble generation modules 410a, 410b, . . . , 410k, . . . , and 410n may also be connected and installed only on the sidewalls 430c of the treating bath 210. FIG. 13 is a second exemplary view illustrating the layout of the plurality of bubble generation modules that constitute the first substrate treating apparatus. FIG. 14 is a third exemplary schematic view illustrating the layout of the plurality of bubble generation modules that constitute the first substrate treating apparatus.

The bubble generation modules 410a, 410b, . . . , 410k, . . . , and 410n may be connected and installed on the bottom surface 430b of the treating bath 210, the sidewalls 430c of the treating bath 210, or both. The bubble generation modules 410a, 410b, . . . , 410k, . . . , and 410n may have various layouts, and the layout of the bubble generation modules 410a, 410b, . . . , 410k, . . . , and 410n may be determined in consideration of the direction in which the substrates W are immersed in the substrate treating solution L within the treating bath 210, the direction in which the substrate treating solution L is supplied into the treating bath 210 by the treating solution source 220, and the position of the flow direction control modules 420 within the treating bath 210.

The bubble generation modules 410a, 410b, . . . , 410k, . . . , and 410n may provide the same type of gas into the treating bath 210. For example, the bubble generation modules 410a, 410b, . . . , 410k, . . . , and 410n may provide N₂ gas into the treating bath 210, but the present disclosure is not limited thereto. Alternatively, the bubble generation modules 410a, 410b, . . . , 410k, . . . , and 410n may provide different types of gases into the treating bath 210. Yet alternatively, some of the bubble generation modules 410a, 410b, . . . , 410k, . . . , and 410n may provide the same type of gas into the treating bath 210, while other bubble generation modules may provide different types of gases.

Meanwhile, when a single bubble generation module 410 is connected and installed within the treating bath 210, the bubble generation module 410 may be connected and installed on the bottom surface 430b of the treating bath 210, but the present disclosure is not limited thereto. Alternatively, the bubble generation module 410 may also be connected and installed on the sidewalls 430c of the treating bath 210.

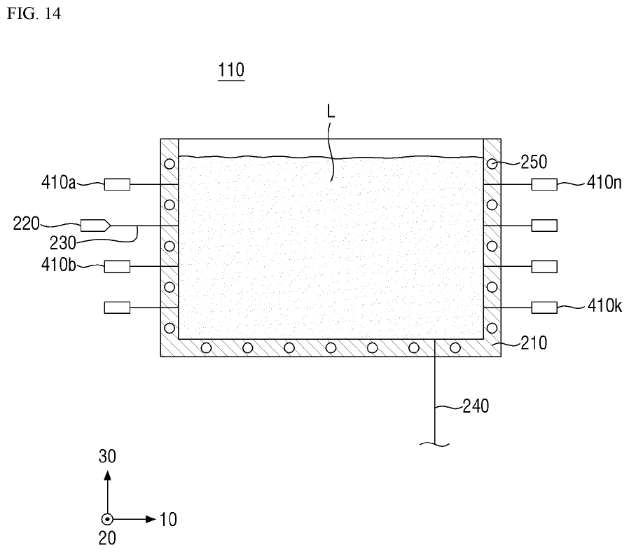

Referring again to FIG. 5, the flow direction control modules 420 are installed on the inner surface of the treating bath 210. The flow direction control modules 420 may be formed as structures with a predetermined shape. Here, the predetermined shape may be a polygonal shape (e.g., a triangular or rectangular shape), a circular shape, or an oval shape. Referring to FIG. 15, the flow direction control modules 420 may change the direction of the bubbles 510 within the substrate treating solution L.

When a flow rate is generated within the treating bath 210, the bubbles 510 may move within the substrate treating solution L according to the generated flow rate. However, as previously described, since there is no resistance in the substrate treating solution L, a faster flow rate in a particular area (e.g., the center area) may increase the etching amount for the substrates W. Also, although the bubbles 510 can reduce the dispersion of the substrate treating solution L, a higher flow rate of bubbles 510 tends to decrease the etch rate for the substrates W.

The direction of the bubbles 510 may be controlled through the flow direction control modules 420. When the bubbles 510 collide with the flow direction control modules 420, which is a structure fixed at a particular position, the movement direction of the bubbles 510 may change. This can prevent the bubbles 510 from being concentrated in the particular area and allow for uniform flow within the substrate treating solution L. FIG. 15 is an exemplary schematic view illustrating the role of the flow direction control modules that constitute the first substrate treating apparatus.

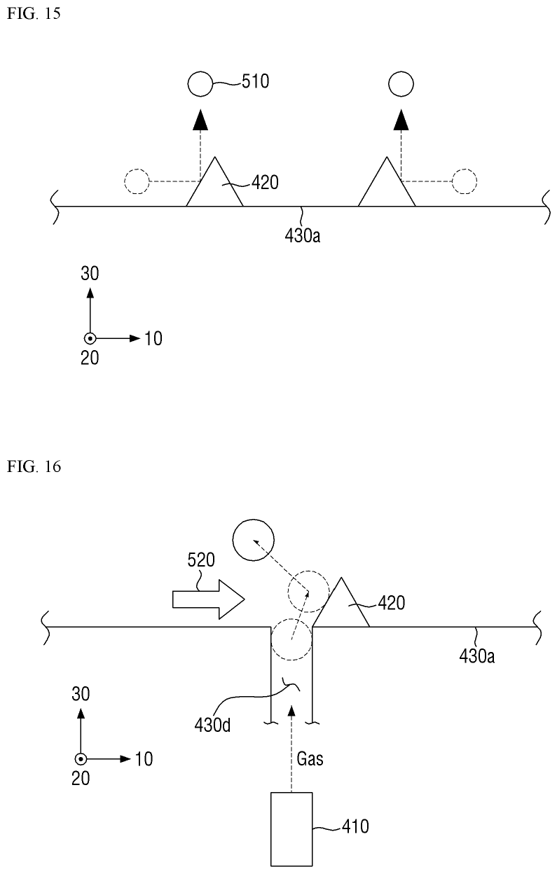

Referring to FIG. 16, the flow direction control modules 420 may be installed at the entrance through which gas is injected into the treating bath 210 through the bubble generation module 410. Accordingly, the flow direction control modules 420 can direct the flow of the substrate treating solution L toward the hole where the bubbles 510 are generated. FIG. 16 is a first exemplary schematic view illustrating the layout of the flow direction control modules that constitute the first substrate treating apparatus.

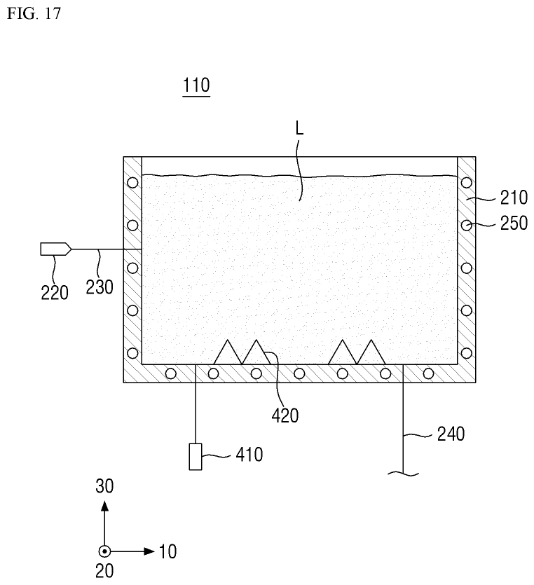

Referring to FIG. 17, the flow direction control modules 420 may be densely formed in the center area of the treating bath 210 to prevent the flow rate of the substrate treating solution L from becoming fast in the center area. As previously described, since a faster flow rate in the center area may increase the etching amount for the substrates W, the flow direction control modules 420 may be densely formed in the center area of the treating bath 210. However, the present disclosure is not limited to this. The flow direction control modules 420 may also be densely formed in other areas within the treating bath 210. The area in which the flow direction control modules 420 are densely located may vary depending on the etching amount for the substrates W.

A plurality of flow direction control modules 420 may be provided in the treating bath 210. In this case, the flow direction control modules 420 may be installed on the bottom surface 430b of the treating bath 210. However, the present disclosure is not limited to this. Alternatively, the flow direction control modules 420 may also be installed on the sidewalls 430c of the treating bath 210, or on both the bottom surface 430b and sidewalls 430c of the treating bath 210. FIG. 17 is a second exemplary schematic view illustrating the layout of the flow direction control modules that constitute the first substrate treating apparatus.

As the flow direction control modules 420 have various shapes or layouts within the treating bath 210, the flow direction control modules 420 can control flow direction, i.e., the angle of the substrate treating solution L or bubbles 510. Moreover, the flow direction control modules 420 can also control flow speed, i.e., the movement speed of the substrate treating solution L or bubbles 510. For example, in response to the bubbles 510 colliding with the flow direction control modules 420, not only the direction of the bubbles 510 may change, but also the movement speed of the bubbles 510 may decrease.

Meanwhile, the flow direction control modules 420, which are installed within the treating bath 210, may not only change the flow direction of the substrate treating solution L, but also induce the changed flow of the substrate treating solution to detach the bubbles 510 while passing by gas piping.

In summary, referring to FIGS. 1 through 17, hybrid equipment including the first and second substrate treating apparatuses 110 and 120, as well as the bubble generation module 410 and flow direction control modules 420 that can be installed within the first substrate treating apparatus 110, have been described. According to embodiments of the present disclosure, flow rate can be increased by reducing the size of the bubbles 510 to make the substrate treating solution L uniformly contact the surface of the substrates W, and dispersion can be reduced accordingly. By installing structures (i.e., the flow direction control modules 420) within the hybrid equipment, the internal flow can be controlled, and at the same time, the bubbles 510 can be discharged toward an N₂ pipe to control the size of the bubbles 510.

Embodiments of the present disclosure have been described above with reference to the accompanying drawings, but the present disclosure is not limited thereto and may be implemented in various different forms. It will be understood that the present disclosure can be implemented in other specific forms without changing the technical spirit or gist of the present disclosure. Therefore, it should be understood that the embodiments set forth herein are illustrative in all respects and not limiting.

What is claimed is:

1. A substrate treating apparatus comprising:
a treating bath providing space for receiving a substrate treating solution for treating substrates;
a treating solution source providing the substrate treating solution into the treating bath such that the substrates are immersed and treated in the substrate treating solution; and
a bubble generation module connected to the treating bath and generating bubbles in the substrate treating solution by injecting gas.

2. The substrate treating apparatus of claim 1, further comprising:
a flow direction control module installed in the treating bath and controlling a movement direction of the bubbles.

3. The substrate treating apparatus of claim 2, wherein
the flow direction control module is a motionless structure, and
in response to the bubbles colliding with the motionless structure, the movement direction of the bubbles changes.

4. The substrate treating apparatus of claim 2, wherein the flow direction control module is installed at an entrance through which the gas is injected into the treating bath.

5. The substrate treating apparatus of claim 2, wherein a plurality of flow direction control modules are provided and are densely located in a particular area within the treating bath.

6. The substrate treating apparatus of claim 5, wherein the particular area where the plurality of flow direction control modules are densely located varies depending on a treating amount for the substrate.

7. The substrate treating apparatus of claim 2, wherein the flow direction control module controls a movement direction of the bubbles.

8. The substrate treating apparatus of claim 1, wherein the bubble generation module controls an amount of the bubbles.

9. The substrate treating apparatus of claim 8, wherein the bubble generation module controls the amount of the bubbles based on an injection speed of the gas.

10. The substrate treating apparatus of claim 8, wherein the bubble generation module controls the amount of the bubbles based on a treating amount for the substrate.

11. The substrate treating apparatus of claim 1, wherein a size of the bubbles is controlled based on a treating amount for the substrate.

12. The substrate treating apparatus of claim 11, wherein
the size of the bubbles is controlled based on shear stress, and
the shear stress is related to a flow rate of the substrate treating solution.

13. The substrate treating apparatus of claim 11, wherein the flow rate of the substrate treating solution is controlled based on at least one of a position of the treating solution source, a number of treating solution sources, a supply speed of the substrate treating solution, a position of the bubble generation module, a number of bubble generation modules, and a gas injection speed of the bubble generation module(s).

14. The substrate treating apparatus of claim 1, wherein the gas is a gas containing a nitrogen component.

15. A substrate treating system comprising:
a first substrate treating apparatus treating a substrate;
a second substrate treating apparatus treating the substrate; and
a transfer unit transferring the substrate between the first and second substrate treating apparatuses,
wherein
the first substrate treating apparatus includes a treating bath providing space for receiving a substrate treating solution for treating substrates, a treating solution source providing the substrate treating solution into the treating bath such that the substrates are immersed and treated in the substrate treating solution, and a bubble generation module connected to the treating bath and generating bubbles in the substrate treating solution by injecting gas, and
the first and second substrate treating apparatuses differ from each other in terms of how they treat the substrate.

16. The substrate treating system of claim 15, wherein
the first substrate treating apparatus is batch-type equipment, and
the second substrate treating apparatus is single-type equipment.

17. The substrate treating system of claim 15, wherein the first substrate treating apparatus further includes a flow direction control module installed in the treating bath and controlling a movement direction of the bubbles.

18. The substrate treating system of claim 17, wherein the flow direction control module controls a movement speed of the bubbles.

19. The substrate treating system of claim 15, wherein
a size of the bubbles is controlled based on shear stress, and
the shear stress is related to a flow rate of the substrate treating solution.

20. A substrate treating apparatus comprising:
a treating bath providing space for receiving a substrate treating solution for treating substrates;
a treating solution source providing the substrate treating solution into the treating bath such that the substrates are immersed and treated in the substrate treating solution;
a bubble generation module connected to the treating bath and generating bubbles in the substrate treating solution by injecting gas; and
a flow direction control module installed in the treating bath and controlling a movement direction and movement speed of the bubbles,
wherein
the flow direction control module is a motionless structure installed at an entrance through which the gas is injected into the treating bath,
in response to the bubbles colliding with the motionless structure, the movement direction of the bubbles changes,
a size of the bubbles is controlled based on shear stress and a size of a hole, which is formed to penetrate the treating bath to provide the gas into the treating bath, and
the shear stress is related to a flow rate of the substrate treating solution.
